(19) United States
(12) Patent Application Publication
(10) Pub. No.: US 2011/0056530 A1
(43) Pub. Date: Mar. 10, 2011

(54) HIGH CONCENTRATED PHOTOVOLTAIC (HCPV) SOLAR CELL MODULE

(76) Inventor: Liann-Be CHANG, Kwei-Shan (TW)

(21) Appl. No.: 12/877,329

(22) Filed: Sep. 8, 2010

(30) Foreign Application Priority Data
Sep. 8, 2009 (TW) 098130183

(51) Int. Cl. H01L 31/0232; H01L 35/00; H01L 31/042

(52) U.S. Cl. 136/200; 136/259; 136/246

(57) ABSTRACT

A high concentrated photovoltaic (HCPV) solar cell module, comprising: a set of Fresnel lenses, a Group III-V semiconductor solar cell, and a substrate used to carry said Group III-V semiconductor solar cell. Wherein, said substrate is made of material of good heat dissipation, for assisting heat dissipation. Said set of Fresnel lenses includes a plurality of stacked-up Fresnel lenses, thus concentrating sunlights to said Group III-V semiconductor solar cell with a significantly higher concentration ratio. As such, in addition to the advantages of small volume, light weight, and cost saving, it is devoid of the problem of a conventional single piece Fresnel lens of insufficient light concentration capability. Therefore, said Group III-V semiconductor solar cell is capable of receiving much more sunlights per unit area, and achieving high photoelectric conversion efficiency; meanwhile, reducing number and area required by said Group III-V semiconductor solar cell, thus achieving reduction of production cost.

### BACKGROUND OF THE INVENTION

1. Field of the Invention

The present invention relates to a high concentrated photovoltaic (HCPV) solar cell module, and in particular to a HCPV solar cell module utilizing Fresnel lens to concentrate sunlight.

2. The Prior Arts

Presently, in the energy regeneration resources, the high concentrated photovoltaic (HCPV) solar energy power generation system is the most promising one for its various advantages of material saving, low power cost, and high power generation efficiency, and it is generally considered as most suitable for used in a solar energy power plant, and is a mainstay and key-point in the development of the solar energy industry in the future. The high concentrated photovoltaic (HCPV) solar energy power generation system combining the high power Group III-V semiconductor solar cell and Fresnel Lens catches most of the attention for its capability of reducing the power generation cost significantly.

Refer to FIG. 1 for a high concentrated photovoltaic (HCPV) solar cell module of the prior art. As shown in FIG. 1, the thin and light-weight Fresnel lens 10 replaces the conventional optical lens, such that in addition to reducing volume and weight significantly, it is capable of achieving fast production and low cost; a Group III-V semiconductor solar cell 20 of smaller area is disposed opposite to the Fresnel lens 10, such that sunlight irradiated upon the Fresnel lens 10 are concentrated and focused onto the Group III-V semiconductor solar cell 20, hereby generating electricity for outputting to the subsequent stages of electronic equipment as required, and also dissipating heat generated in this process through a heat dissipation base 30.

However, the Fresnel lens utilized in a conventional high concentrated photovoltaic (HCPV) solar cell module is a structure made of a single layer of material, and its light concentration capability is rather insufficient, thus the high photoelectric conversion efficiency of the Group III-V semiconductor solar cell can not be fully utilized, therefore its power output is inadequate, and the cost benefit of the overall high concentrated photovoltaic (HCPV) solar cell module is not satisfactory.

### SUMMARY OF THE INVENTION

In view of the problems and shortcomings of the prior art, a major objective of the present invention is to provide a high concentrated photovoltaic (HCPV) solar cell module, which utilizes a plurality of stacked-up Fresnel lenses in achieving focusing sunlight with a high concentration ratio, thus enhancing and raising the photoelectric conversion efficiency of the Group III-V semiconductor solar cell, in solving the problems and shortcomings of the prior art.

In order to achieve the above mentioned objective, the present invention provides a high concentrated photovoltaic (HCPV) solar cell module, comprising: a set of Fresnel lenses made of a plurality of thin, light-weight, and low-cost Fresnel lenses, a Group III-V semiconductor solar cell of high photoelectric conversion efficiency, and a substrate. In other words, instead of a single piece Fresnel lens utilized in the prior art, the present invention provides two or more Fresnel lenses, that are stacked on each other in an up-and-down manner and is disposed opposite and above the Group III-V semiconductor solar cell; and when it is irradiated by the sunlights, it will focus and concentrate the sunlights on the Group III-V semiconductor solar cell with high concentration ratio, in achieving high photoelectric conversion efficiency and large power output, thus reducing the number of the Group III-V semiconductor solar cells and high concentrated photovoltaic (HCPV) solar cell modules required, hereby lowering its production cost. In the process mentioned above, the temperature of the Group III-V semiconductor solar cells will be increased through the sunlights absorbed, and the heat thus generated will be dissipated into the ambient air through a substrate located at the bottom of the Group III-V semiconductor solar cell. Moreover, the present invention may also include a heat-electric conversion cell or a long wavelength solar cell, wherein, heat is converted into electricity, hereby further increasing its overall photoelectric conversion efficiency and the power generation efficiency.

Further scope of the applicability of the present invention will become apparent from the detailed descriptions given hereinafter. However, it should be understood that the detailed descriptions and specific examples, while indicating preferred embodiments of the present invention, are given by way of illustration only, since various changes and modifications within the spirit and scope of the present invention will become apparent to those skilled in the art from this detailed descriptions.

### BRIEF DESCRIPTION OF THE DRAWINGS

The related drawings in connection with the detailed descriptions of the present invention to be made later are described briefly as follows, in which:

FIG. 1 is schematic diagram of a high concentrated photovoltaic (HCPV) solar cell module of the prior art;

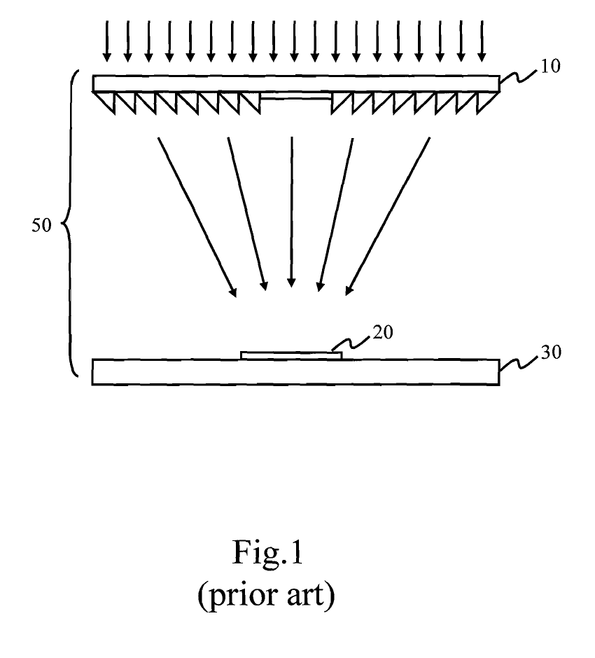

FIG. 2 is schematic diagram of a high concentrated photovoltaic (HCPV) solar cell module according to a first embodiment of the present invention;

FIG. 3 is a schematic diagram of a Fresnel lens utilized in a high concentrated photovoltaic (HCPV) solar cell module according to another embodiment of the present invention;

FIG. 4 is schematic diagram of a high concentrated photovoltaic (HCPV) solar cell module according to a second embodiment of the present invention;

FIG. 5 is schematic diagram of a high concentrated photovoltaic (HCPV) solar cell module according to a third embodiment of the present invention; and

FIG. 6 is schematic diagram of a high concentrated photovoltaic (HCPV) solar cell module according to a fourth embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

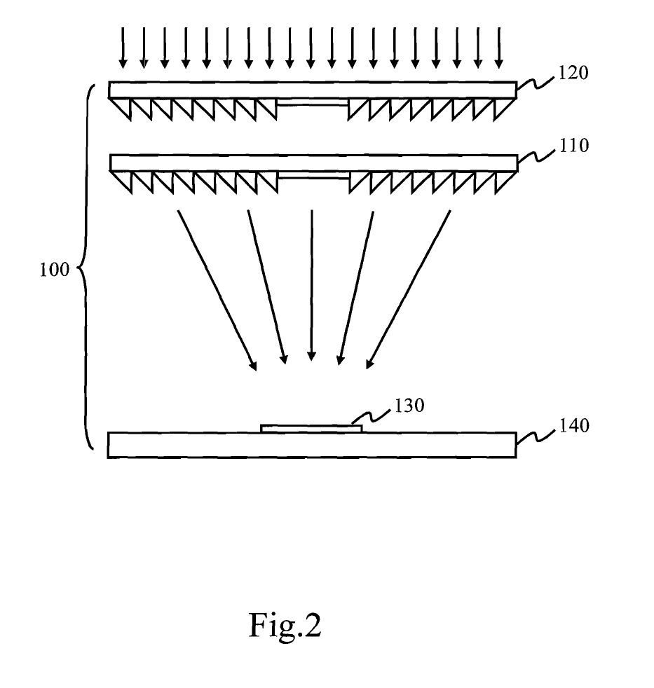

Firstly, refer to FIG. 2 for a schematic diagram of a high concentrated photovoltaic (HCPV) solar cell module according to a first embodiment of the present invention. As shown in FIG. 2, a high concentrated photovoltaic (HCPV) solar cell module 100 comprises: a set of Fresnel lenses used to concentrate sunlights, and is composed of a first Fresnel lens 110 and a second Fresnel lens 120; a Group III-V semiconductor solar cell 130, and a substrate 140.

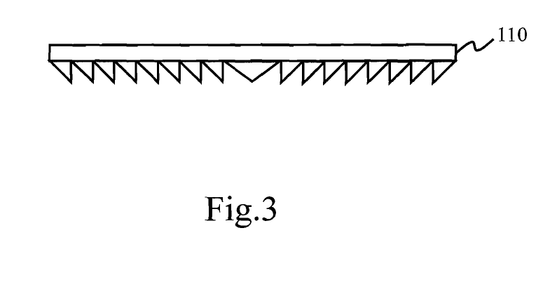

In the structure mentioned above, the set of Fresnel lenses are made of a plurality of Fresnel lenses, in the present embodiment, two Fresnel lenses are utilized as an example, but in actual application, it is not limited to this. Moreover, in the present invention, the set of Fresnel lenses are designed to produce varied power output depending on the angles formed by the Fresnel lenses. The first Fresnel lens 110 and the second Fresnel lens 120 are made of material of excellent optical property, such as the light transmission resin PMMA, PC, or PE, with its structure having saw-tooth mirrors on its lower side with gradually increasing angles outward, and with its texture made through utilizing light interference, diffraction, and receiving angle. In general, its focal length is designed as from 1 mm to 100 cm, with a light concentration ratio of 2×-1000×. In case that the first and second Fresnel lenses 110 and 120 are made of PMMA material, the flexibility of the Fresnel lenses can make them operate smoothly with the solar cells. Refer to FIG. 3 for a schematic diagram of a Fresnel lens utilized in a high concentrated photovoltaic (HCPV) solar cell module according to another embodiment of the present invention (which is indicated with a first Fresnel lens 110), and that is provided with similar functions of light focusing. In the present invention, the first and second Fresnel lenses 110 and 120 are stacked up in an up-and-down manner, so as to raise the light concentration ratio significantly, and gather much more sunlights for focusing and concentrating them onto the Group III-V semiconductor solar cell 130. By way of example, in case that the light concentration ratio of the first and second Fresnel lenses 110 and 120 are 15× respectively, then the light concentration ratio after stacking them up will become 15*15=225×. Naturally, in practice, more than two Fresnel lenses can be stacked up, for example, the light concentration ratio of three stacked-up Fresnel lenses each having light concentration ratio of 15×, can be 15*15*15=3375×. Therefore, the light concentration ratio of a plurality of stacked-up Fresnel lenses of the present invention can be in a range of about 3× to 3000×.

The Group III-V semiconductor solar cell 130 is disposed opposite to the first and second Fresnel lenses 110 and 120, and absorbs the sunlights focused and concentrated by the first and second Fresnel lenses 110 and 120, and converts them into electricity for output. Compared with the ordinary silicon crystal solar cell, the Group III-V semiconductor solar cell 130 is able to absorb energy of wider range of sunlight spectrum, thus its photoelectric conversion efficiency is increased significantly. In the present embodiment, the Group III-V semiconductor solar cell 130 is made of the materials selected from a group consisting of GaAs, GaP, InP, AlGaAs, GaInAs, AlGaP, GaInP, AlGaAsP, InGaAsP, AlGaInAsP, or their combinations. Alternatively, the Group III-V semiconductor solar cell 130 can be made of the materials selected from a group consisting of GaN, InN, GaAl, AlGaN, AlInN, AlInGaN, or their combinations. The substrate 140 is designed to have good heat dissipation capability, and is made of materials selected from a group consisting of: Ag, Cu, Al, Ni, Au, or their alloys. Therefore, the high temperature generated by the Group III-V semiconductor solar cell 130 through the sunlights concentrated by the first and second Fresnel lenses 110 and 120 can be dissipated into the ambient air through a substrate 140 disposed at the bottom of the solar cell 130, so that it may operate in an appropriate temperature, hereby prolonging the service life of the Group III-V semiconductor solar cell 130.

In passing through the second Fresnel lens 120 and the first Fresnel lens 100 sequentially, sunlights will be concentrated onto the Group III-V semiconductor solar cell 130 with a high concentration ratio, thus raising its photoelectric conversion efficiency significantly, achieving higher power output, while reducing the number required and area occupied by the Group III-V semiconductor solar cell 130, in realizing the reduction of its production cost.

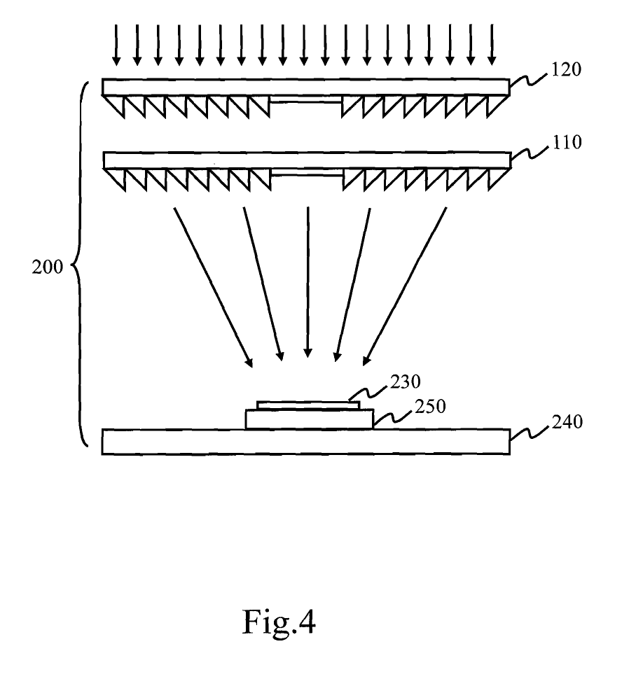

Refer to FIG. 4 for a schematic diagram of a high concentrated photovoltaic (HCPV) solar cell module 200 according to a second embodiment of the present invention. In this embodiment, a heat-electric conversion cell 250 is disposed between a Group III-V semiconductor solar cell 230 and a substrate 240, thus generating electricity through a heat-electric effect. As such, the heat generated by the solar cell 230 is converted directly into electricity by the heat-electric conversion cell 250, thus enabling the entire Group III-V semiconductor solar cell 230 to have good heat-electric conversion efficiency.

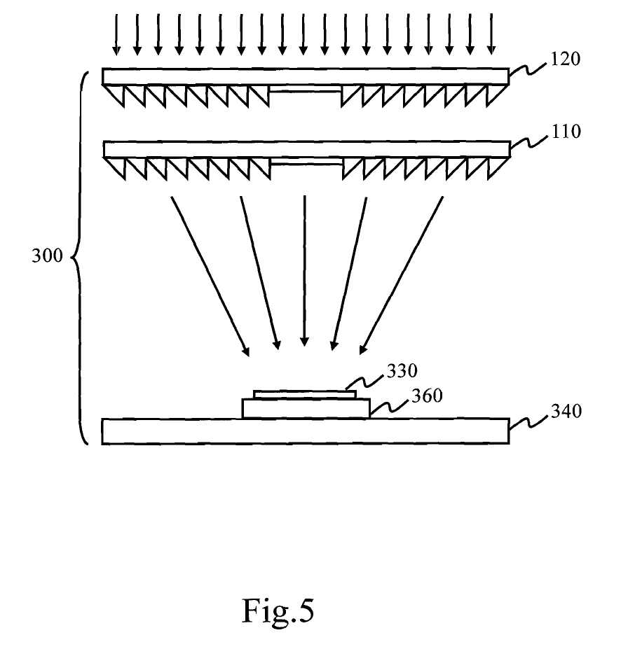

In addition, refer to FIG. 5 for a schematic diagram of a high concentrated photovoltaic (HCPV) solar cell module 300 according to a third embodiment of the present invention. In this embodiment, a long wavelength solar cell 360 is disposed between a Group III-V semiconductor solar cell 330 and a substrate 340, for assisting in absorbing sunlights of long wavelength, in raising the photoelectric conversion efficiency of the solar cell module 300.

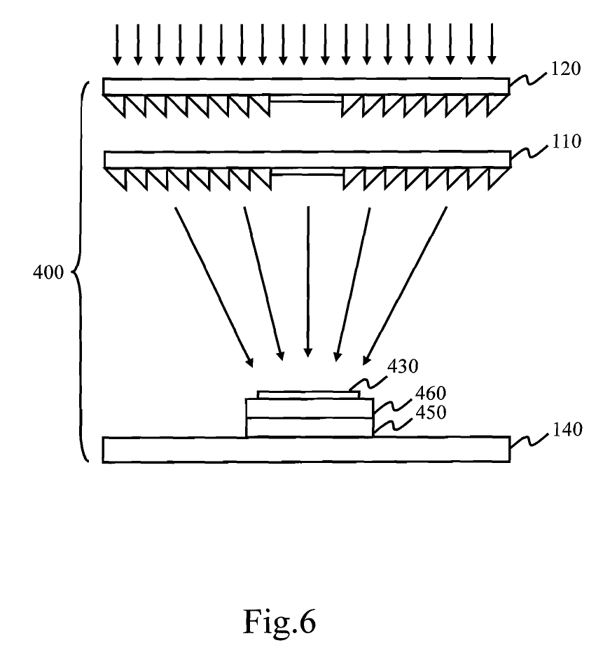

Finally, refer to FIG. 6 for a schematic diagram of a high concentrated photovoltaic (HCPV) solar cell module 400 according to a fourth embodiment of the present invention. In this embodiment, both a heat-electric conversion cell 450 and a long wavelength solar cell 460 are disposed between a Group III-V semiconductor solar cell 430 and a substrate 140, hereby achieving even higher photoelectric conversion efficiency, and larger power output.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A high concentrated photovoltaic (HCPV) solar cell module, comprising:
a substrate;
a Group III-V semiconductor solar cell disposed on said substrate; and
a set of Fresnel lenses, including at least a first Fresnel lens and a second Fresnel lens, said first Fresnel lens is disposed above said Group III-V semiconductor solar cell, and said second Fresnel lens is disposed above said first Fresnel lens, such that sunlight passing through said first and said second Fresnel lenses are focused and concentrated onto said Group III-V semiconductor solar cell with a high concentration ratio.

2. The high concentrated photovoltaic (HCPV) solar cell module as claimed in claim 1, further comprising: at least a heat-electric conversion cell disposed between said substrate and said Group III-V semiconductor solar cell.

3. The high concentrated photovoltaic (HCPV) solar cell module as claimed in claim 1, further comprising: at least a long wavelength solar cell disposed between said substrate and said Group III-V semiconductor solar cell.

4. The high concentrated photovoltaic (HCPV) solar cell module as claimed in claim 1, further comprising: at least said heat-electric conversion cell disposed on said substrate; and at least said long wavelength solar cell disposed between said heat-electric conversion cell and said Group III-V semiconductor solar cell.

5. The high concentrated photovoltaic (HCPV) solar cell module as claimed in claim 1, wherein said substrate is made to have good heat dissipation capability.

6. The high concentrated photovoltaic (HCPV) solar cell module as claimed in claim 5, wherein said substrate is made of materials selected from a group consisting of: Ag, Cu, Al, Ni, Au, or their alloys.

7. The high concentrated photovoltaic (HCPV) solar cell module as claimed in claim 1, wherein said Group III-V semiconductor solar cell is made of materials selected from a group consisting of: GaAs, GaP, InP, AlGaAs, GaInAs, AlGaP, GaInP, AlGaAsP, InGaAsP, AlGaInAsP, or their combinations.

8. The high concentrated photovoltaic (HCPV) solar cell module as claimed in claim 1, wherein said Group III-V semiconductor solar cell is made of materials selected from a group consisting of: GaN, InN, GaAl, AlGaN, AlInN, AlInGaN, or their combinations.

9. The high concentrated photovoltaic (HCPV) solar cell module as claimed in claim 1, wherein said first and said second Fresnel lenses are made of material of PMMA, PC, or PE.

10. The high concentrated photovoltaic (HCPV) solar cell module as claimed in claim 1, wherein said light concentration ratios of said first and said second Fresnel lenses are 2×-1000× respectively.

11. The high concentrated photovoltaic (HCPV) solar cell module as claimed in claim 1, wherein focal lengths of said first and said second Fresnel lenses are 1 mm-100 cm respectively.
